(19) United States
(12) Patent Application Publication
(10) Pub. No.: US 2006/0011957 A1
(43) Pub. Date: Jan. 19, 2006

(54) Information detecting device for photo film

(75) Inventors: Shinichi Takahashi, Kanagawa (JP); Toshio Itoh, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/174,632

(22) Filed: Jul. 6, 2005

(30) Foreign Application Priority Data
Jul. 16, 2004 (JP) 2004-210149

(51) Int. Cl. H01L 31/113

(52) U.S. Cl. 257/292

(57) ABSTRACT

A photo film scanner for photo film having an image frame has plural light sources, which apply illuminating light to the photo film, and include a multi-chip LED packages having plural chips for emitting the illuminating light at wavelengths different from one another. Plural photo receptors receive light from the photo film upon incidence of the illuminating light thereon, so as to retrieve frame position information and frame size information of the image frame. A wavelength control unit is responsive to setting of one detecting mode included in plural detecting modes, and drives a related chip within each multi-chip LED package related to a predetermined wavelength, for example one for an orange or white color. Emission of an unrelated chip within the multi-chip LED package unrelated to the predetermined wavelength is suppressed, to restrict the illuminating light to the predetermined wavelength for the one detecting mode.

### BACKGROUND OF THE INVENTION

1. Field of the Invention

The present invention relates to an information detecting device for a photo film. More particularly, the present invention relates to an information detecting device for a photo film, in which information previously required for image reading can be precisely obtained even with a simple structure.

2. Description Related to the Prior Art

A photo film scanner is disclosed in JP-A 2004-118061 for optically reading an image from photo film. Examples of photo films include color negative photo film, monochromatic photo film, reversal photo film and the like. Light is applied to the photo film. The light passed through the photo film is picked up by a CCD image sensor or other image pickup devices, for photoelectric conversion. An image frame is read from the photo film, so the photo film scanner creates and records digital image data.

There is a photo film holder or carrier in the photo film scanner. A feeding path is formed through the photo film holder. The photo film is passed through the feeding path, moves to reach a reading position where opposed to the CCD image sensor, which reads the image frame in the photo film. For suitable reading of the image frame, it is necessary to detect a position of the frame on the photo film, and a size of the image. Therefore, at first, existence or lack of the photo film detected in a specific position in the feeding path before the reading of the image frame, so as to check suitability in the initial feeding of the photo film. After this, the position of the image frame with reference to a feeding direction is detected. Also, a size of the image frame in the photo film width direction is detected.

Such preliminary information of the image frame is detected by an information sensor unit. The information sensor unit includes a light source and a photo receptor. The light source applies illuminating light to the photo film. The information sensor unit is opposed to the light source, and receives the illuminating light passed through the photo film. A position of the frame on the photo film, and a size of the image are detected according to a difference between a support density of density of an unexposed portion of the photo film and density of the image frame as an exposed portion. One example of the light source is an LED light source, which is disclosed in U.S. Pat. No. 5,260,740 (corresponding to JP-A 4-350640). An example of photo receptor is a CCD line sensor and PSD (position sensitive detector).

The feeding path in the photo film holder is provided with a plurality of information sensor units associated with the preliminary information of plural items. Examples of information sensor units include a photo film detecting sensor, a frame detecting sensor and a size detecting sensor. The photo film detecting sensor detects existence or lack of the photo film. The frame detecting sensor detects the image frame in the feeding direction on the photo film. The size detecting sensor detects a dimension of the image on the photo film width direction.

It is necessary suitably to select a wavelength of illuminating light according to a support color of the photo film for the purpose of obtaining high precision in detection of the information sensor unit. So JP-A 2004-118061 discloses a selected wavelength in view of suitability for color negative photo film. In the information sensor unit, the light source includes LEDs for light emission at the wavelength of 600-620 nm for the orange color.

Various types of photo films are known, including monochromatic photo film and reversal photo film. As those have a support being different in the support color between them. An optimized wavelength of light emission of illuminating light is different between the photo film types. In JP-A 2004-118061, a wavelength of illuminating light is selected for one particular type of photo film. However, it is impossible to optimize precision in the detection for nearly every type of photo film other than the particular type.

The preliminary information to be detected in reading the image frame is plural items as described above. A plurality of the information sensor unit must be installed for the purposes associated with the items. If the number of light sources is determined in consideration of the number of types of photo film, it will be extremely difficult to maintain a space for accommodation of the information sensor unit. An information detecting device must be complicated structurally, to raise the manufacturing cost seriously.

### SUMMARY OF THE INVENTION

In view of the foregoing problems, an object of the present invention is to provide an information detecting device for a photo film, in which information previously required for image reading can be precisely obtained even with a simple structure.

In order to achieve the above and other objects and advantages of this invention, an information detecting device for a photo film scanner for reading an image frame on photo film is provided. At least one light source applies illuminating light to the photo film, the light source including a light-emitting element package having plural light-emitting elements of a chip type, packaged therein, for emitting the illuminating light at wavelengths different from one another. At least one photo receptor receives light from the photo film upon incidence of the illuminating light thereon, so as to retrieve at least any one of frame position information and frame size information of the image frame. A wavelength control unit controls an illuminating wavelength of the light-emitting elements of the chip type.

Specifically, an information detecting device for photo film having an image frame is provided. At least one light source applies illuminating light to the photo film, the light source including a light-emitting element package having plural light-emitting elements of a chip type, packaged therein, for emitting the illuminating light at wavelengths different from one another. At least one photo receptor receives light from the photo film upon incidence of the illuminating light thereon, so as to retrieve at least any one of frame position information and frame size information of the image frame. A wavelength control unit is responsive to setting of one detecting mode included in plural detecting modes, for driving a related light-emitting element within the light-emitting element package related to a predetermined wavelength, and for suppressing emission of an unrelated light-emitting element within the light-emitting element package unrelated to the predetermined wavelength, to restrict the illuminating light to the predetermined wavelength for the one detecting mode.

The information detecting device is used in a photo film scanner for reading the image frame on the photo film.

The light source includes a package array constituted by a plurality of the light-emitting element package.

Furthermore, a photo film feeding mechanism feeds the photo film longitudinally. The package array extends in a photo film width direction of the photo film, and the photo receptors scan the photo film by reception of light during feeding of the photo film.

The wavelength control unit selectively assigns the N wavelengths for respectively ones of the plural detecting modes different from one another.

The plural detecting modes include two detecting modes adapted to reading the photo film of first and second types.

The first type is color negative photo film, and a wavelength of a range of an orange color is assigned selectively among the N wavelengths.

The second type is at least one of reversal photo film and monochromatic photo film, and a wavelength of a range of a white color is assigned selectively among the N wavelengths.

The at least one photo receptor comprises first to Pth photo receptors associated with respective detecting modes different from one another among the plural detecting modes. The at least one light source comprises first to Pth light sources disposed in association with respectively the first to Pth photo receptors.

The first to Pth light sources include respectively a package array constituted by a plurality of the light-emitting element package. The wavelength control unit causes a plurality of the light-emitting element to illuminate together for an equal wavelength distribution in each of the first to Pth light sources.

In one preferred embodiment, furthermore, a type detector operates before the light source and the photo receptor, and retrieves type information of the photo film from the photo film. The wavelength control unit causes the light source to illuminate at the predetermined wavelength being selected according to a detection result of the type detector.

The at least one photo receptor comprises first and second photo receptors, the at least one light source comprises first and second light sources disposed in association with respectively the first and second photo receptors. The N wavelengths comprise first, second and third wavelengths. The first wavelength corresponds to a first one of the plural detecting modes, and is adapted to light emission of the first light source. The second wavelength corresponds to a second one of the plural detecting modes, and is adapted to light emission of the first light source. The third wavelength corresponds to a third one of the plural detecting modes, and is adapted to light emission of the second light source.

The second light source and the second photo receptor are driven before the first light source and the first photo receptor, and adapted to check of presence of the photo film.

The third wavelength is a wavelength range of a green color.

The light-emitting element package has a pedestal portion for securing of the light-emitting elements thereto, and the light source has a circuit board for keeping the plurality of the light-emitting element package arranged with the pedestal portion.

The light-emitting element package has a transparent cover, secured to the pedestal portion, for protecting the light-emitting elements by covering.

The N wavelengths comprise wavelengths of ranges of green, orange and white colors.

### BRIEF DESCRIPTION OF THE DRAWINGS

The above objects and advantages of the present invention will become more apparent from the following detailed description when read in connection with the accompanying drawings, in which:

FIG. 1 is a block diagram illustrating a digital laboratory system;

FIG. 2A is a perspective view illustrating a package array where light-emitting element packages are arranged on a circuit board;

FIG. 2B is a perspective view illustrating one of the light-emitting element packages having a pedestal and a transparent cover;

FIG. 2C is a top plan illustrating the same as the FIG. 2B;

FIG. 3 is a table illustrating a relationship between plural detecting modes and colors of light;

FIG. 4A is a graph illustrating an illuminating characteristic of a green light-emitting element;

FIGS. 4B and 4C are graphs illustrating illuminating characteristics of orange and white light-emitting elements;

FIG. 5A is a perspective view illustrating a preferred embodiment in which photo film types are automatically detected; and

FIG. 5B is a flow chart illustrating operation of the structure of FIG. 5A.

### DETAILED DESCRIPTION OF THE PREFERRED EMBODIMENT(S) OF THE PRESENT INVENTION

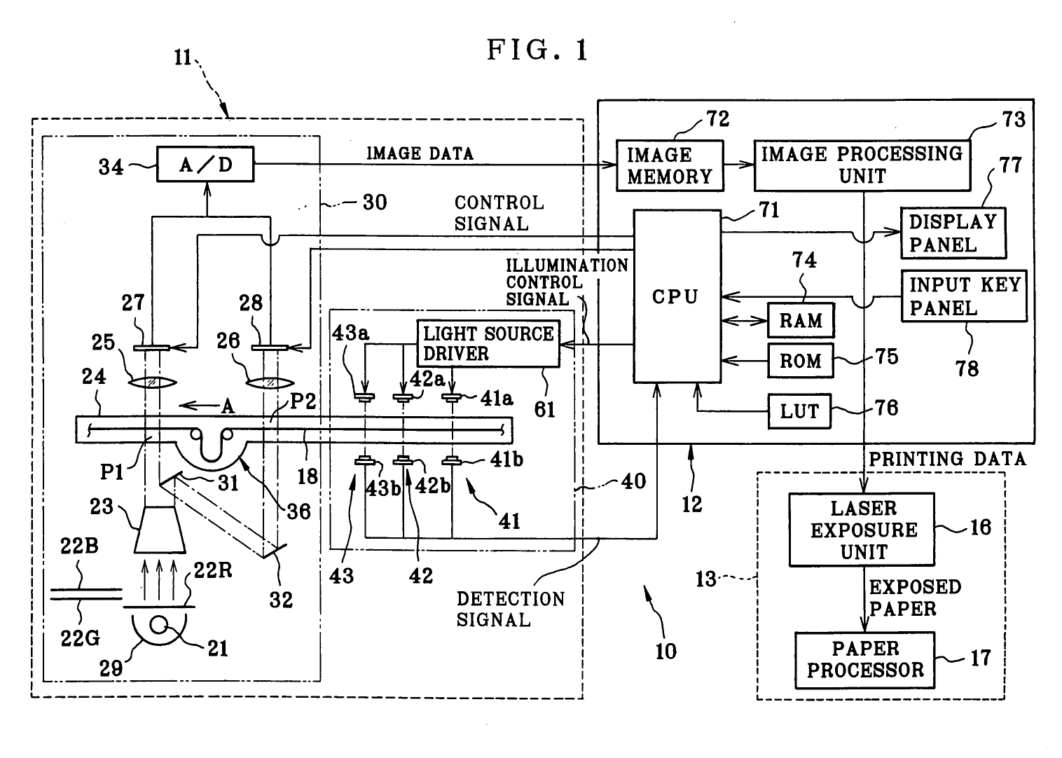

In FIG. 1, a digital laboratory system 10 is illustrated, and includes a photo film scanner 11, an image processor 12 and image forming equipment or image output equipment 13. The image forming equipment 13 includes a laser exposure unit 16 and a paper processor 17. Photo film 18 is set into the photo film scanner 11, which reads frames photoelectrically, and creates image data of a digital form to send the image data to the image processor 12. The image processor 12 processes the image data, to produce printing data. The image processor 12 is on the basis of a personal computer, workstation or suitable electronic equipment, and operates as a controller for controlling the entirety of the digital laboratory system 10.

The laser exposure unit 16 scans photographic paper by use of laser according to printing data, to expose an image on the photographic paper. The paper processor 17 processes the exposed photographic paper for development, to obtain a photographic print.

The photo film scanner 11 includes an image reader 30 and an information sensor group 40. The image reader 30 includes a halogen lamp 21, color separation filters 22R, 22G and 22B, a diffusion box 23, a photo film holder 24 or carrier, image pickup lenses 25 and 26, a fine scan CCD image sensor 27, and a pre-scan CCD image sensor 28. The information sensor group 40 operates before image reading, and detects preliminary information which includes frame position information of a frame position on the photo film, and a frame size.

The halogen lamp 21 emits white light to read images of frames. A reflector 29 reflects light from the halogen lamp 21 toward the front. The color separation filters 22R, 22G and 22B are disposed in a manner movable into and out of a light path of the halogen lamp 21, and separate the white light into color light of Red color, Green color and Blue color. The three-color light is passed through the diffusion box 23, and illuminates the photo film 18 one color after another. An inner surface of the diffusion box 23 is a reflection surface, which reflects incident light and diffuses it for the purpose of diffusion, to reduce irregularity in the light amount.

Light exiting from the diffusion box 23 is directed to first and second reading positions P1 and P2 on a feeding path of the photo film holder 24. The first reading position P1 is predetermined in front of the fine scan CCD image sensor 27. The second reading position P2 is predetermined in front of the pre-scan CCD image sensor 28. The first reading position P1 is on an extension of an exit of the diffusion box 23, and receives direct passage of light from the diffusion box 23. A mirror 31 is disposed between the diffusion box 23 and the photo film holder 24, and reflects a partial component of light from the diffusion box 23 toward one side position. There is a mirror 32 to which light reflected by the mirror 31 is directed. The mirror 32 reflects the light additionally, and directs the same to the reading position P2.

Light passed through the photo film 18 in the reading positions P1 and P2 is focused by the image pickup lenses 25 and 26 on a detecting plane of the CCD image sensors 27 and 28. An A/D converter 34 is connected with the CCD image sensors 27 and 28, which convert image light photoelectrically, to supply the A/D converter 34 with an electric signal of an analog form according to a level of the received light. The A/D converter 34 converts the analog electric signal into a digital form of image data, which is sent to the image processor 12. An object of the pre-scanning is to determine a reading condition, such as a charge storing time, prior to fine scanning to obtain main image data. Reading in the pre-scanning is at a smaller number of pixels than in fine scanning. Recording density of each image frame is measured according to the pre-scanning data obtained in the pre-scanning, to determine a condition of reading.

The photo film holder 24 includes a guide panel and a feed roller. The guide panel is disposed according to a width of the photo film 18, and defines a feeding path for the photo film 18. The feed roller supplies the photo film 18 to the reading positions P1 and P2 upon loading in the photo film holder 24. The second reading position P2 for the pre-scanning is upstream from the first reading position P1 for the fine scanning as viewed in the feeding direction A of the photo film 18 indicated by the arrow. The number of pixels in the reading is small in the pre-scanning. So the feeding speed is higher in the pre-scanning than the fine scanning. A photo film reservoir or buffering mechanism 36 among feed rollers is disposed between the first and second reading positions P1 and P2, and causes the photo film 18 partially to stay for reservation by forming a curve or loop of the photo film 18, so as to absorb a difference in the feeding speed between a high speed for the pre-scanning and a low speed for the fine scanning.

It is necessary precisely to determine a frame position of a frame on the photo film, and a size of the frame on the photo film for the purpose of pre-scanning and fine scanning. The information sensor group 40 is positioned upstream from the image reader 30, and detects preliminary information required for reading the image frame. Specifically, examples of the preliminary information are photo film detecting information, frame position information, and frame size information. The photo film detecting information is information of existence of the photo film 18 having reached a predetermined position in a feeding path. The frame position information is position information of the frame on the photo film in the feeding direction. The frame size information is size information of the frame on the photo film in the photo film width direction. In order to retrieve such information, the information sensor group 40 includes a photo film detecting sensor 41, frame detecting sensor 42, and size detecting sensor 43.

The detecting sensors 41, 42 and 43 are respectively constituted by multi-purpose light sources 41a, 42a and 43a and photo receptors 41b, 42b and 43b. The multi-purpose light sources 41a, 42a and 43a apply illuminating light to the photo film 18. The photo receptors 41b, 42b and 43b, in a form of line sensor, receive light from the photo film 18 upon transmission of the illuminating light. The photo film detecting sensor 41 is a first sensor, and detects a reach of a front end of the photo film 18 to the information sensor group 40 to check presence of the photo film 18.

The frame detecting sensor 42 detects a position of a frame on the photo film by evaluating a density difference between a density of a portion of the image and a density of an unrecorded portion or photo film support density, so as to detect an edge of a frame on the photo film.

The size detecting sensor 43 is a third sensor to detect a size. Examples of a frame size include a full size, and a panoramic size different from the full size. The panoramic size has the same horizontal dimension (in the feeding direction) as that of the full size, but has a smaller vertical dimension in the photo film width direction. Upper and lower portions of a frame of the panoramic size frame are left blank and unexposed. The size detecting sensor 43 detects a density level of the portions that might be unexposed blank portions in the panoramic size. In the full size, an average density of the frame is high because an image is recorded fully. However, in the panoramic size, a level of measured density is low because of the unexposed blank portion. Thus, the high or low density level can be used for discerning a frame size.

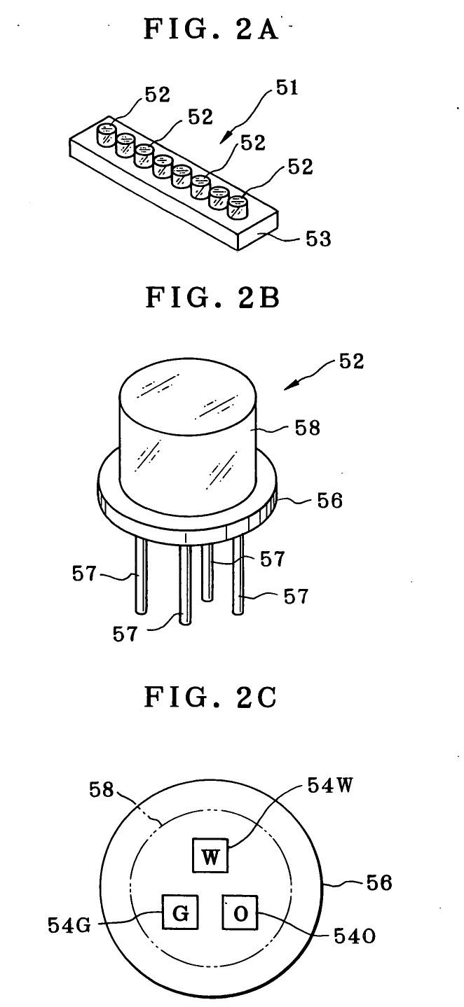

In FIG. 2A, a package array 51 is depicted, and used for each of the multi-purpose light sources 41a, 42a and 43a. The package array 51 includes a plurality of light-emitting units 52 or multi-chip LED packages as light-emitting element packages, arranged on a substrate or circuit board 53 in a line shape. In FIGS. 2B and 2C, each of the multi-chip LED packages 52 includes light-emitting elements 54G, 54O and 54W or LEDs as chips for emitting light in different wavelengths, namely different colors. A support portion or pedestal 56 to define a light-emitting surface is adapted to mount the light-emitting elements 54G, 54O and 54W. Examples of the light-emitting elements 54G, 54O and 54W are light-emitting diodes (LEDs) in a rectangular parallelepipedic form of a chip type. The light-emitting elements 54G, 54O and 54W are combined in a unified form of a package to obtain each of the multi-chip LED packages 52.

A first surface of the support portion or pedestal 56 is provided with contact points and lands. The contact points are used for connection with one of electrodes of the light-emitting elements 54G, 54O and 54W. The lands connect a remaining electrode of the light-emitting elements 54G, 54O and 54W to the pedestal 56 by wire bonding. A second surface of the pedestal 56 has connection leads 57, which connect the multi-chip LED packages 52 to the substrate 53. Among the connection leads 57, a first one is assigned to a positive electrode or common electrode of the light-emitting elements 54G, 54O and 54W. A second, a third and a fourth of the connection leads 57 are assigned to a negative electrode or discrete electrode of the light-emitting elements 54G, 54O and 54W. A transparent cover or dome 58 is fixed on the pedestal 56, and covers and protects the light-emitting elements 54G, 54O and 54W.

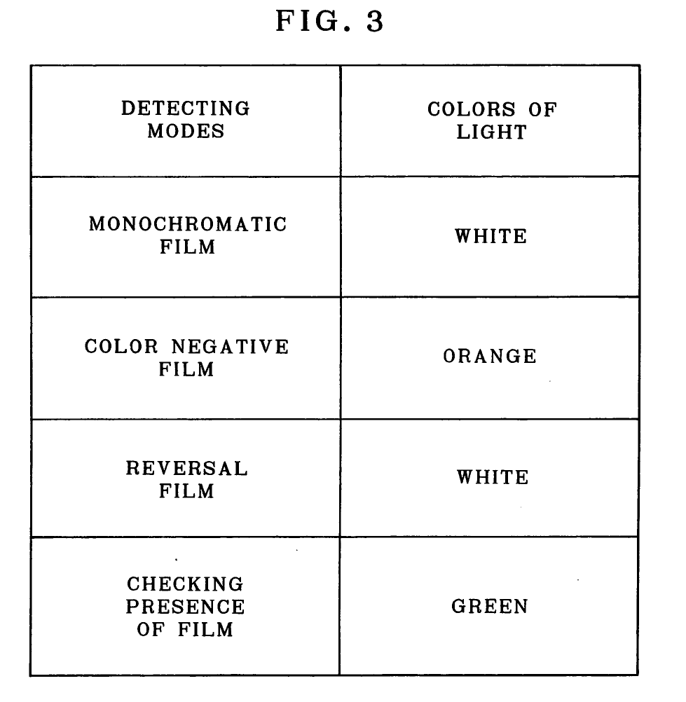

FIG. 3 is a table for a list of used colors of light. A green color is determined for illuminating light suitable for detecting existence of photo film. A white color is determined for illuminating light suitable for a frame position on the photo film and its size with respect to black-and-white photo film and reversal photo film. An orange color is determined for illuminating light suitable for a frame position on the photo film and its size with respect to color negative photo film. The light-emitting elements 54G, 54O and 54W emit light of respectively green, orange and white colors.

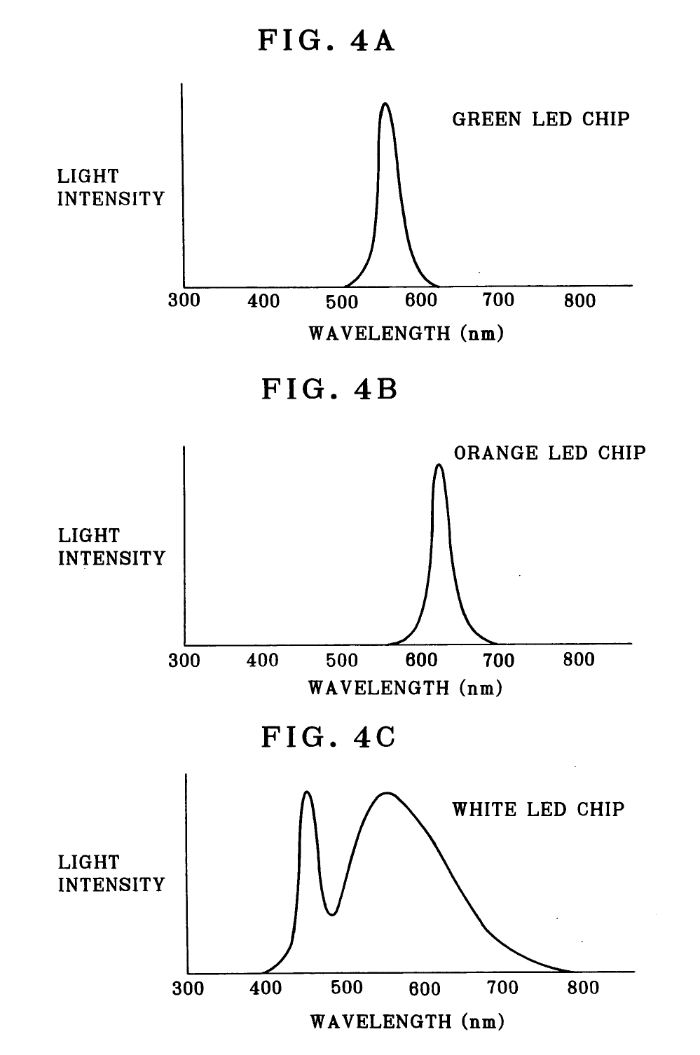

In graphs of FIGS. 4A-4C, characteristics of emission of the light-emitting elements 54G, 54O and 54W are illustrated. FIG. 4A shows distribution in the wavelength of light emitted by the green light-emitting element 54G. FIG. 4B shows distribution in the wavelength of light emitted by the orange light-emitting element 54O. FIG. 4C shows distribution in the wavelength of light emitted by the white light-emitting element 54W.

The multi-chip LED packages 52 are used in the same manner in the detecting sensors 41-43. The photo film detecting sensor 41 operates only by turning on an array of the green light-emitting element 54G among the three-color LEDs. In the frame detecting sensor 42 and the size detecting sensor 43, the three-color LEDs are turned on selectively. The frame detecting sensor 42 and the size detecting sensor 43 illuminate for detection with the color negative photo film by turning on an array of the orange light-emitting element 54O without the white light-emitting element 54W. The frame detecting sensor 42 and the size detecting sensor 43 illuminate for detection with the black-and-white photo film and reversal photo film by turning on an array of the white light-emitting element 54W without the orange light-emitting element 54O. There is a light source driver 61 for driving the multi-chip LED packages 52 with a constant electric current.

The photo receptors 41b, 42b and 43b receive illuminating light from the multi-purpose light sources 41a, 42a and 43a, and output detection signals according to a level of a light amount. An example of each of the photo receptors 41b, 42b and 43b is a CCD line sensor, PSD (position sensitive detector) or the like.

The image processor 12 includes a CPU 71 as a wavelength control unit, an image memory 72, an image processing unit 73, a RAM 74, a ROM 75, a LUT (look-up table memory) 76, a display panel 77, and an input key panel 78. The display panel 77 as a user interface displays a menu pattern for inputting signals for operating the digital laboratory system 10, and also displays image frames read by the photo film scanner 11. The input key panel 78 includes a keyboard, but may be provided with a mouse or other pointing devices. An operator starts up the digital laboratory system 10 by use of the display panel 77 and the input key panel 78.

The image memory 72 stores image data of an image frame output by the A/D converter 34. The image processing unit 73 reads the image data from the image memory 72, processes the image data by gradation correction, shading correction, and other image processing, and produces printing data. The laser exposure unit 16 is supplied with the printing data.

The CPU 71 controls the image processor 12 and the photo film scanner 11 connected with the image processor 12. The ROM 75 stores various control programs and data of settings according to which the CPU 71 operates. The RAM 74 is a work memory to which data is written during running of the CPU 71.

The CPU 71 causes the light source driver 61 to drive the light-emitting elements 54G, 54O and 54W selectively, to set a selected one of preset wavelengths of the illuminating light. Also, the CPU 71 causes the light source driver 61 to adjust a light amount of the light-emitting elements 54G, 54O and 54W according to PWM (Pulse Width Modulation) control in which a duty factor of driving pulses between a pulse width and period is changed. A combination of the CPU 71 and the information sensor group 40 constitutes an information detecting device of the invention.

The LUT 76 is referred to by the CPU 71 in order to change over the illuminating light wavelength of the frame detecting sensor 42 and the size detecting sensor 43. The LUT 76 stores information of photo film types an associated color of illuminating light, for example, color negative photo film and orange color, reversal photo film and white color, and white-and-black photo film and white color. An operator inputs one of the photo film types with the input key panel 78 by observing the photo film 18 with his or her eyes. The CPU 71 determines an illuminating light color by referring to the LUT 76 according to the input type, and causes the light source driver 61 to change over the frame detecting sensor 42 and the size detecting sensor 43 for one particular color. In the photo film detecting sensor 41, the green light-emitting element 54G is turned on for green light irrespective of a photo film type.

The operation of the above construction is described now. To read the photo film 18, an operator sets the photo film 18 in the photo film holder 24 in the photo film scanner 11, and operates the input key panel 78 to input a type of the photo film 18. The photo film 18 starts being fed upon inputting of a command signal of starting the reading. The CPU 71, responsive to the start of the feeding, evaluates the film type, and determines the color of light in the frame detecting sensor 42 and the size detecting sensor 43, and drives the information sensor group 40. When the photo film 18 reaches the photo film detecting sensor 41 in the feeding in a proper manner, the photo film detecting sensor 41 detects the photo film 18, and sends a detection signal to the CPU 71. The CPU 71 starts measuring a feeding amount of the photo film 18 with reference to the sensor position. Furthermore, the photo film 18 moves to reach the frame detecting sensor 42. The frame detecting sensor 42 detects a front edge of a frame on the photo film, and sends a detection signal to the CPU 71. The CPU 71, responsive to this, determines the front edge of the frame on the photo film. After this, the size detecting sensor 43 detects the size information.

It is possible to detect necessary information precisely, because the colors of emitting light of the detecting sensors 41-43 can be determined suitably for photo film type and types of preliminary information. The use of the multi-chip LED packages 52 in the multi-purpose light sources 41a, 42a and 43a having the light-emitting elements 54G, 54O and 54W is effective in reducing a space of installation of multi-purpose light sources, simplifying the structure of the photo film scanner, and the like, as compared with a more complicated structure in which the detecting sensors 41-43 might be differently constructed.

The use of the multi-chip LED packages 52 common between the detecting sensors 41-43 is effective in facilitating the assembling process of the equipment or photo film scanner. Should different types of light sources having LEDs be assembled suitably without fail, occurrence of errors in the assembly will be more probable. However, the feature of the invention can make the assembly easy and free from such a problem. The problem is the more likely to occur according to a larger number of the sensors. However, the feature of the invention can be effective even in such a more serious problem.

Preliminary information is obtained by the information sensor group 40, to determine a frame position on the photo film and its size. Then images are pre-scanned and then finely scanned. The image processor 12 subjects the image data to image processing, and creates printing data by conversion. The image forming equipment 13 exposes photographic paper according to the printing data, and processes the photographic paper, to obtain a photographic print.

In the above embodiment the three sensors 41-43 are installed. However, a fourth sensor can be used, for example a sensor for detecting DX code or bar code information recorded on photo film of IX240 type as an example of preliminary information. Also, the light-emitting elements 54G, 54O and 54W are three in each one of the multi-chip LED packages 52. However, two or four or more LEDs may be mounted in each of the multi-chip LED packages 52. The number of the LEDs can be determined suitably according to kinds of preliminary information and photo film types.

Furthermore, light-emitting colors of the light-emitting elements 54G, 54O and 54W in the multi-chip LED packages 52 can be other than the green, orange and white colors, as desired in suitably considering the type of the preliminary information and types of the photo film 18. For example, for black-and-white photo film, illuminating light for detecting the frame position in a photo film and a frame size may be a blue color in addition to a white color.

Furthermore, colors of the light-emitting elements in the multi-chip LED packages 52 can be mixed to change over the colors of light. This is advantageous in that even a color difficult to obtain by a simple LED will be available by addition or mixture of plural colors of LEDs. Before the practical use of detection, it is preferable that the illuminating light is turned on experimentally. Mixed color of the illuminating light optimized for the photo film 18 can be checked and verified.

In the above embodiment, an operator manually determines and inputs photo film types. However, a photo film type can be determined automatically by use of reading of DX code or the like, to change over illuminating light colors automatically. Furthermore, a checking tape on an end of the photo film may be used for automatically detecting a photo film type.

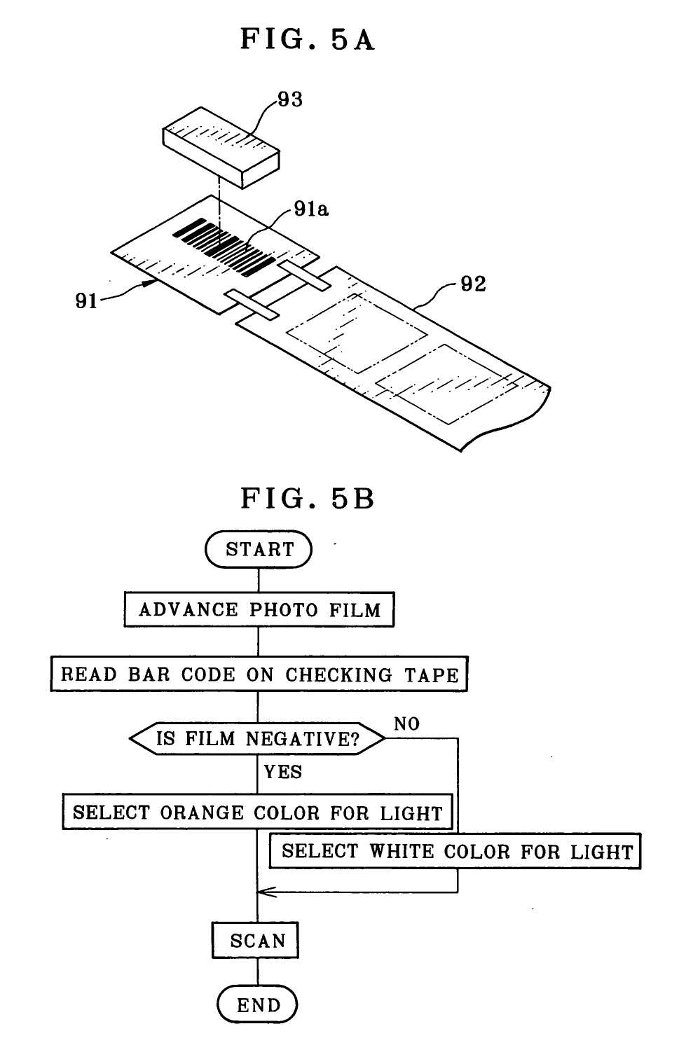

In FIG. 5A, checking tape 91 is attached to one front end of the photo film 92 by an adhesive tape or sticker. The checking tape 91 has been issued for each of customer orders for printing. A bar code 91a as photo film detection information is printed on the checking tape 91, and has ordering information which is information of an ordering date, numbers of prints, photo film types. The photo film 92 is photographically processed together with the checking tape 91 attached thereto, and then loaded in the photo film holder 24 for photo film scanning.

There is a bar code reader 93 as type detector disposed on a feeding path. In FIG. 5B, the bar code reader 93 reads the bar code 91a while the photo film 92 moves. Then the CPU 71 determines the type of the photo film 92 according to photo film type information included in data of the checking tape 91, and determines a selected one of the plural colors for light emission of the multi-chip LED packages 52. If the photo film 92 is color negative photo film, the color is determined orange color. If the photo film 92 is reversal photo film or black-and-white photo film, the color is determined white.

Also, known variants of multi-chip packages of light-emitting diodes can be used, for example, structures disclosed in U.S. Pat. Nos. 5,266,817 and 6,737,801.

Furthermore, any types of light-emitting elements other than LEDs may be used, for example electroluminescence (EL) devices.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. An information detecting device for a photo film scanner for reading an image frame on photo film, comprising:
at least one light source for applying illuminating light to said photo film, said light source including a light-emitting element package having plural light-emitting elements of a chip type, packaged therein, for emitting said illuminating light at wavelengths different from one another;
at least one photo receptor for receiving light from said photo film upon incidence of said illuminating light thereon, so as to retrieve at least any one of frame position information and frame size information of said image frame; and
a wavelength control unit for controlling an illuminating wavelength of said light-emitting elements of said chip type.

2. An information detecting device as defined in claim 1, wherein said light source includes a package array constituted by a plurality of said light-emitting element package arranged on a support portion.

3. An information detecting device as defined in claim 2, wherein said wavelength control unit is responsive to setting of one detecting mode included in plural detecting modes, for driving a related light-emitting element within said light-emitting element package related to a predetermined wavelength, and for suppressing emission of an unrelated light-emitting element within said light-emitting element package unrelated to said predetermined wavelength, to restrict said illuminating light to said predetermined wavelength for said one detecting mode.

4. An information detecting device as defined in claim 3, further comprising a photo film feeding mechanism for feeding said photo film longitudinally; and
wherein said package array extends in a photo film width direction of said photo film, and said photo receptors scan said photo film by reception of light during feeding of said photo film.

5. An information detecting device as defined in claim 3, wherein said wavelength control unit selectively assigns said plural wavelengths of said plural light-emitting elements of said chip type, for respectively ones of said plural detecting modes different from one another.

6. An information detecting device as defined in claim 5, wherein said plural detecting modes include two detecting modes adapted to reading said photo film of first and second types.

7. An information detecting device as defined in claim 6, wherein said first type is color negative photo film, and a wavelength of a range of an orange color is assigned selectively among said plural wavelengths.

8. An information detecting device as defined in claim 6, wherein said second type is at least one of reversal photo film and monochromatic photo film, and a wavelength of a range of a white color is assigned selectively among said plural wavelengths.

9. An information detecting device as defined in claim 3, further comprising a type detector for operating before said light source and said photo receptor, for retrieving type information of said photo film from said photo film;
wherein said wavelength control unit causes said light source to illuminate at said predetermined wavelength being selected according to a detection result of said type detector.

10. An information detecting device as defined in claim 3, wherein said at least one photo receptor comprises first to Pth photo receptors associated with respective detecting modes different from one another among said plural detecting modes;
said at least one light source comprises first to Pth light sources disposed in association with respectively said first to Pth photo receptors;
said wavelength control unit causes a plurality of said light-emitting element to illuminate together for an equal wavelength distribution in each of said first to Pth light sources.

11. An information detecting device as defined in claim 3, wherein said plural light-emitting elements of said chip type further include an additional light-emitting element for emitting illuminating light adapted to checking presence of said photo film.

12. An information detecting device as defined in claim 11, wherein a wavelength of said additional light-emitting element is a wavelength range of a green color.

13. An information detecting device as defined in claim 3, wherein said at least one photo receptor comprises first and second photo receptors, said at least one light source comprises first and second light sources disposed in association with respectively said first and second photo receptors;
said wavelengths being different from one another comprise first, second and third wavelengths;
said first wavelength corresponds to a first one of said plural detecting modes, and is adapted to light emission of said first light source;
said second wavelength corresponds to a second one of said plural detecting modes, and is adapted to light emission of said first light source; and
said third wavelength corresponds to a third one of said plural detecting modes, and is adapted to light emission of said second light source.

14. An information detecting device as defined in claim 1, wherein said wavelengths different from one another comprise wavelengths of ranges of green, orange and white colors.

15. An information detecting device for photo film having an image frame, comprising:
at least one light source for applying illuminating light to said photo film, said light source including a light-emitting element package having plural light-emitting elements of a chip type, packaged therein, for emitting said illuminating light at wavelengths different from one another;
at least one photo receptor for receiving light from said photo film upon incidence of said illuminating light thereon, so as to retrieve at least any one of frame position information and frame size information of said image frame; and
a wavelength control unit, responsive to setting of one detecting mode included in plural detecting modes, for driving a related light-emitting element within said light-emitting element package related to a predetermined wavelength, and for suppressing emission of an unrelated light-emitting element within said light-emitting element package unrelated to said predetermined wavelength, to restrict said illuminating light to said predetermined wavelength for said one detecting mode.

16. An information detecting device as defined in claim 15, wherein said plural light-emitting elements are N light-emitting elements of said chip type for light emission at N wavelengths to emit said illuminating light.

17. An information detecting device as defined in claim 16, wherein said information detecting device is used in a photo film scanner for reading said image frame on said photo film.

18. An information detecting device as defined in claim 16, wherein said light source includes a package array constituted by a plurality of said light-emitting element package.

19. An information detecting device as defined in claim 18, further comprising a photo film feeding mechanism for feeding said photo film longitudinally; and
wherein said package array extends in a photo film width direction of said photo film, and said photo receptors scan said photo film by reception of light during feeding of said photo film.

20. An information detecting device as defined in claim 18, wherein said wavelength control unit selectively assigns said N wavelengths for respectively ones of said plural detecting modes different from one another.

21. An information detecting device as defined in claim 20, wherein said plural detecting modes include two detecting modes adapted to reading said photo film of first and second types.

22. An information detecting device as defined in claim 21, wherein said first type is color negative photo film, and a wavelength of a range of an orange color is assigned selectively among said N wavelengths.

23. An information detecting device as defined in claim 21, wherein said second type is at least one of reversal photo film and monochromatic photo film, and a wavelength of a range of a white color is assigned selectively among said N wavelengths.

24. An information detecting device as defined in claim 18, wherein said at least one photo receptor comprises first to Pth photo receptors associated with respective detecting modes different from one another among said plural detecting modes;
said at least one light source comprises first to Pth light sources disposed in association with respectively said first to Pth photo receptors.

25. An information detecting device as defined in claim 24, wherein said first to Pth light sources include respectively a package array constituted by a plurality of said light-emitting element package;
said wavelength control unit causes a plurality of said light-emitting element to illuminate together for an equal wavelength distribution in each of said first to Pth light sources.

26. An information detecting device as defined in claim 18, further comprising a type detector for operating before said light source and said photo receptor, for retrieving type information of said photo film from said photo film;
wherein said wavelength control unit causes said light source to illuminate at said predetermined wavelength being selected according to a detection result of said type detector.

27. An information detecting device as defined in claim 18, wherein said at least one photo receptor comprises first and second photo receptors, said at least one light source comprises first and second light sources disposed in association with respectively said first and second photo receptors;
said N wavelengths comprise first, second and third wavelengths;
said first wavelength corresponds to a first one of said plural detecting modes, and is adapted to light emission of said first light source;
said second wavelength corresponds to a second one of said plural detecting modes, and is adapted to light emission of said first light source; and
said third wavelength corresponds to a third one of said plural detecting modes, and is adapted to light emission of said second light source.

28. An information detecting device as defined in claim 27, wherein said second light source and said second photo receptor are driven before said first light source and said first photo receptor, and adapted to check of presence of said photo film.

29. An information detecting device as defined in claim 28, wherein said third wavelength is a wavelength range of a green color.

30. An information detecting device as defined in claim 18, wherein said light-emitting element package has a pedestal portion for securing of said light-emitting elements thereto; and
said light source has a circuit board for keeping said plurality of said light-emitting element package arranged with said pedestal portion.

31. An information detecting device as defined in claim 30, wherein said light-emitting element package has a transparent cover, secured to said pedestal portion, for protecting said light-emitting elements by covering.

32. An information detecting device as defined in claim 1, wherein said N wavelengths comprise wavelengths of ranges of green, orange and white colors.
